(19) United States
(12) Patent Application Publication
(10) Pub. No.: US 2009/0121262 A1
(43) Pub. Date: May 14, 2009

(54) SEMICONDUCTOR DEVICE CAPABLE OF IMPROVING CONTACT RESISTANCE AND METHOD FOR MANUFACTURING THE SAME

(76) Inventor: Min Jung SHIN, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 11/966,482

(22) Filed: Dec. 28, 2007

(30) Foreign Application Priority Data
Nov. 14, 2007 (KR) 10-2007-0116053

(51) Int. Cl. H01L 29/78

(52) U.S. Cl. 257/288; 257/E29.255

(57) ABSTRACT

A semiconductor device includes a gate formed over a semiconductor substrate; a junction region formed in a portion of the semiconductor substrate corresponding to both sides of the gate and including a projection, of which at least some portion thereof projects from the surface of the portion of the semiconductor substrate; and a contact plug formed so as to cover the projection.

### CROSS-REFERENCE TO RELATED APPLICATIONS

The present application claims priority to Korean patent application number 10-2007-0116053 filed on Nov. 14, 2007, which is incorporated herein by reference in its entirety.

### BACKGROUND OF THE INVENTION

The present invention relates to a semiconductor device and a method for manufacturing the same, and more particularly, to a semiconductor device capable of improving contact resistance and a method for manufacturing the same.

A semiconductor device such as a DRAM (dynamic random access memory) is formed with a contact plug, which electrically connects a junction region (a source region and a drain region) of a transistor with a bit line and a capacitor, over a portion of a semiconductor substrate on both sides of a gate.

Hereafter, a method for manufacturing a semiconductor device in accordance with the prior art including a contact plug forming process will be briefly described.

After a gate insulation layer, a gate conductive layer and a gate hard mask layer are sequentially formed over a semiconductor substrate, the hard mask layer, the gate conductive layer and the gate insulation layer are etched to form a gate over the semiconductor substrate. Impurities are ion implanted into the surface of the semiconductor substrate on both sides of the gate to form a junction region in the surface of the semiconductor substrate corresponding to both sides of the gate.

An insulation layer is formed over the semiconductor substrate formed with the gate and the junction region and then etched to form a contact hole exposing the junction region. After a polysilicon layer is formed over the insulation layer to fill the contact hole, the polysilicon layer is removed to expose the insulation layer, thereby forming a contact plug in contact with the junction region. Thereafter, a bit line in contact with the contact plug is formed over the insulation layer including the contact plug.

Meanwhile, high integration of a semiconductor device narrows a space between the gates. Therefore, the size of a contact plug formed so as to be in contact with a junction region formed in the narrowed space between the gates is also reduced. As the result, it is inevitable in the aforementioned prior art that a contact area between the junction region and the contact plug in the narrowed space between the gates is decreased, thus lowering contact resistance. Such lowering of the contact resistance negatively impacts the characteristics and reliability of the device.

### SUMMARY OF THE INVENTION

Embodiments of the present invention are directed to a semiconductor device capable of improving contact resistance and a method for manufacturing the same.

In one embodiment, a semiconductor device comprises a gate formed over a semiconductor substrate; a junction region formed in a portion of the semiconductor substrate which corresponds to both sides of the gate and includes a projection, of which at least some portion thereof projects from the surface of the semiconductor substrate; and a contact plug formed so as to cover the projection.

The projection is formed of an ion implanted epitaxial silicon layer.

The semiconductor device may further comprise a bit line formed so as to be in contact with the contact plug.

In another embodiment, a method for manufacturing a semiconductor device comprises the steps of forming a gate over a semiconductor substrate; forming a projection over at least some portion of the semiconductor substrate corresponding to both sides of the gate; ion implanting impurities into the projection and a surface of the semiconductor substrate corresponding to both sides of the gate to form a junction region including the projection; and forming a contact plug so as to cover the projection.

The projection is formed of an epitaxial silicon layer.

Forming the projection includes the steps of forming a sacrifice layer over the semiconductor substrate formed with the gate; etching the sacrifice layer to form a hole exposing at least some portion of the semiconductor substrate corresponding to both sides of the gate; forming the epitaxial silicon layer over the exposed portion of the semiconductor substrate; and removing the sacrifice layer.

The epitaxial silicon layer is formed in a selective epitaxial growth process.

The hole is formed so as to have a smaller width than the width of the junction region.

A tilt ion implantation method is used to form the junction region.

The tilt ion implantation method is performed at an implantation angle of 5 to 45°.

The tilt ion implantation method is performed in four directions.

Forming the contact plug includes the steps of forming an insulation layer so as to cover the junction region and the gate over the semiconductor substrate formed with the junction region; etching the insulation layer to form a contact hole exposing the portion of the semiconductor substrate corresponding to both sides of the gate including the junction region; depositing a conductive layer over the insulation layer so as to fill the contact hole; and removing the conductive layer so as to expose the insulation layer.

The method may further comprise, after the step of forming the contact plug, the step of forming a bit line in contact with the contact plug.

### BRIEF DESCRIPTION OF THE DRAWINGS

FIG. 1 is a cross-sectional view illustrating a semiconductor device in accordance with an embodiment of the present invention.

FIGS. 2A through 2H are plan views illustrating the process steps of a method for manufacturing a semiconductor device in accordance with an embodiment of the present invention.

FIGS. 3A through 3H are cross-sectional views taken along the line A-A′ of FIGS. 2A through 2H respectively and illustrating the process steps of a method for manufacturing a semiconductor device in accordance with an embodiment of the present invention.

### DESCRIPTION OF SPECIFIC EMBODIMENTS

In the present invention, a junction region including a projection is formed in a portion of a semiconductor substrate corresponding to both sides of a gate and a contact plug is formed over the junction region so as to cover the projection. Therefore, a contact area between the junction region and the contact plug is increased.

Hereafter, a preferred embodiment of the present invention will be described in detail with reference to the accompanying drawings.

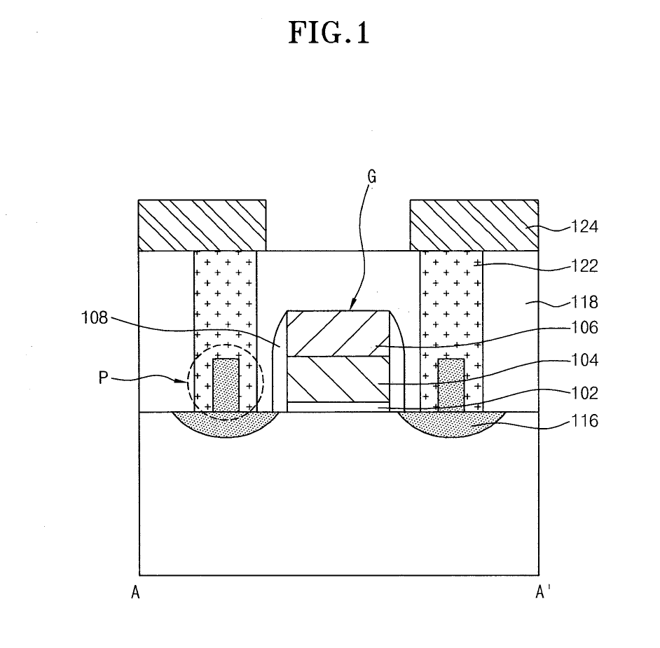

FIG. 1 is a cross-sectional view illustrating a semiconductor device in accordance with an embodiment of the present invention.

As shown, a gate G having a stacked structure of a gate insulation layer 102, a gate conductive layer 104 and a gate hard mask layer 106 is formed over a semiconductor substrate 100, and a spacer 108 is formed on both walls of the gate G. A junction region 116 is formed in a portion of the semiconductor substrate corresponding to both sides of the gate G including the spacer 108. The junction region 116 includes a projection P, at least some portion of which projects from the surface of the semiconductor substrate 100 corresponding to both sides of the gate G. The projection P is formed of an ion implanted epitaxial silicon layer.

A contact plug 122 is formed over the junction region 116 in a shape covering the projection P, and a bit line 124 is formed so as to be in contact with the contact plug 122. Reference number 118 which is not described denotes an insulation layer.

As such, in the semiconductor device of the present invention, since the junction region 116 includes the projection P and the contact plug 122 is formed so as to cover the projection P, the contact area between the junction region 116 and the contact plug 122 is increased. Therefore, since contact resistance between the junction region 116 and the contact plug 122 is improved, the semiconductor device of the present invention has enhanced characteristics and reliability.

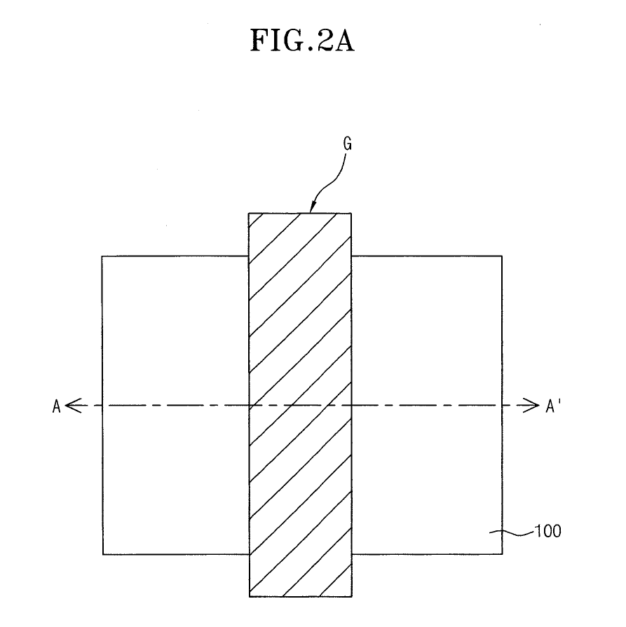

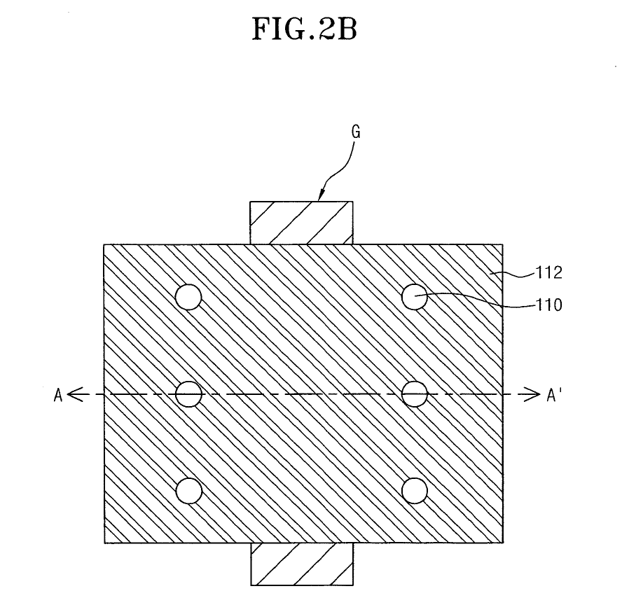

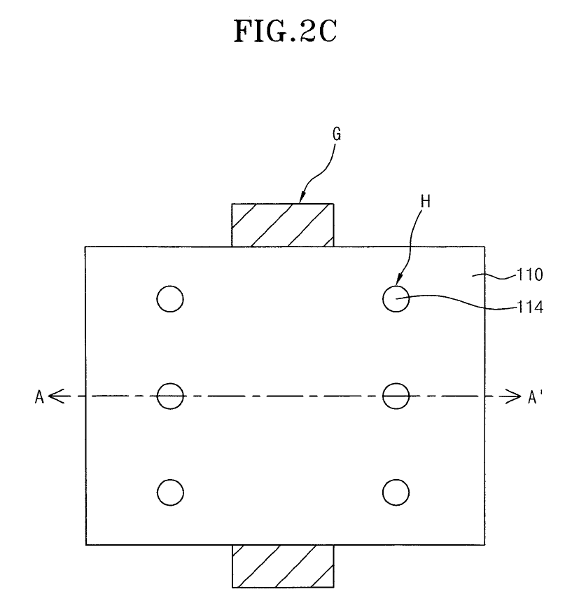

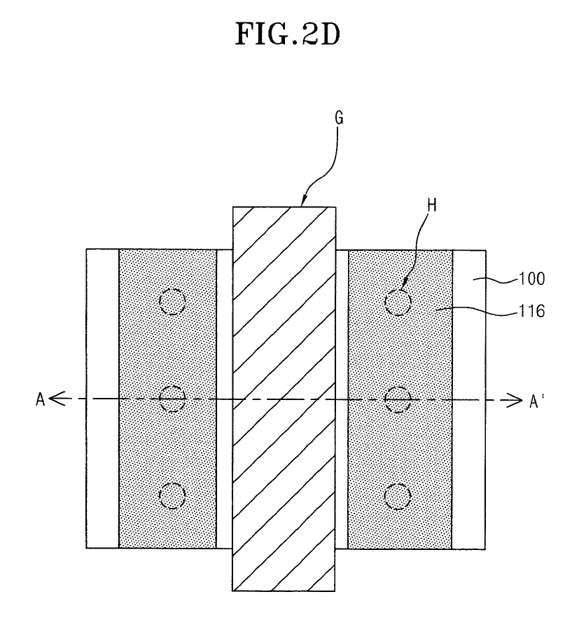

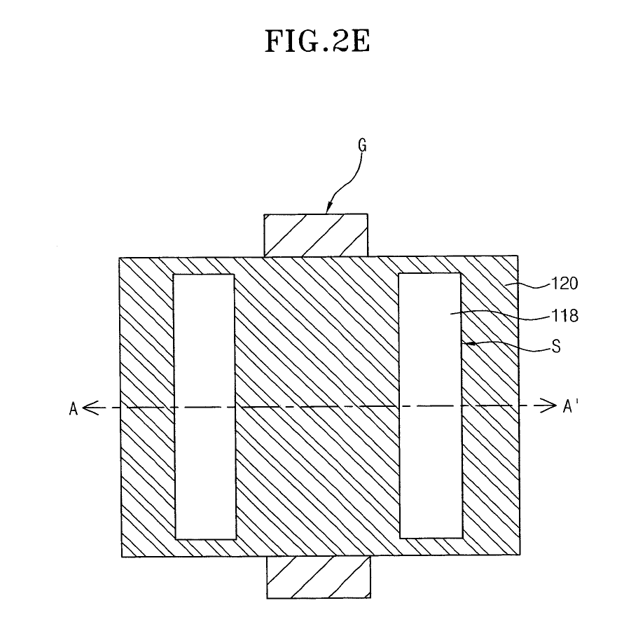

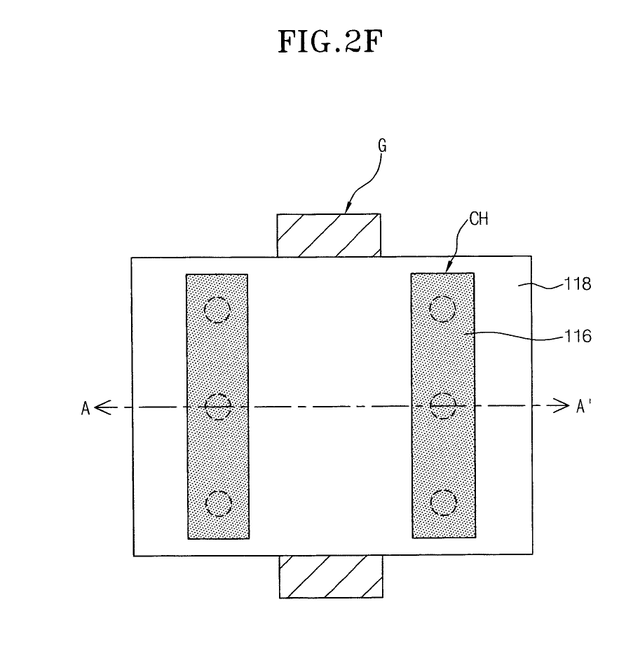

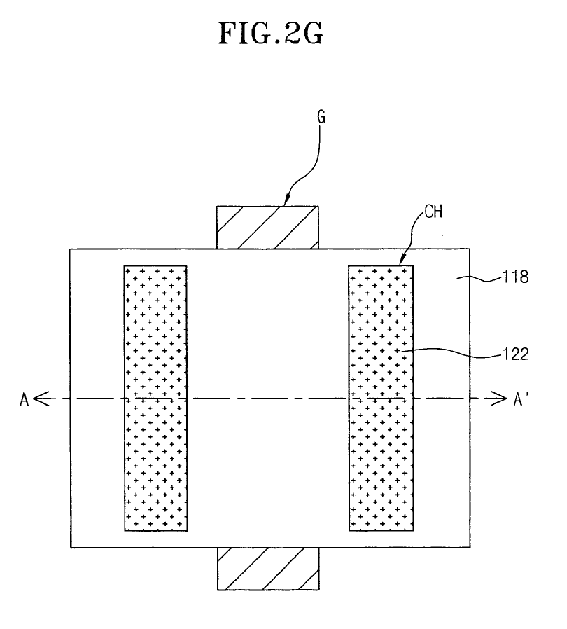

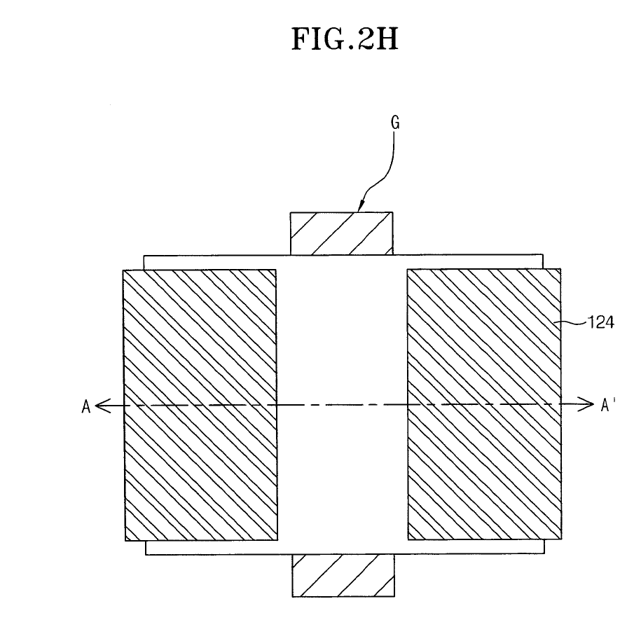

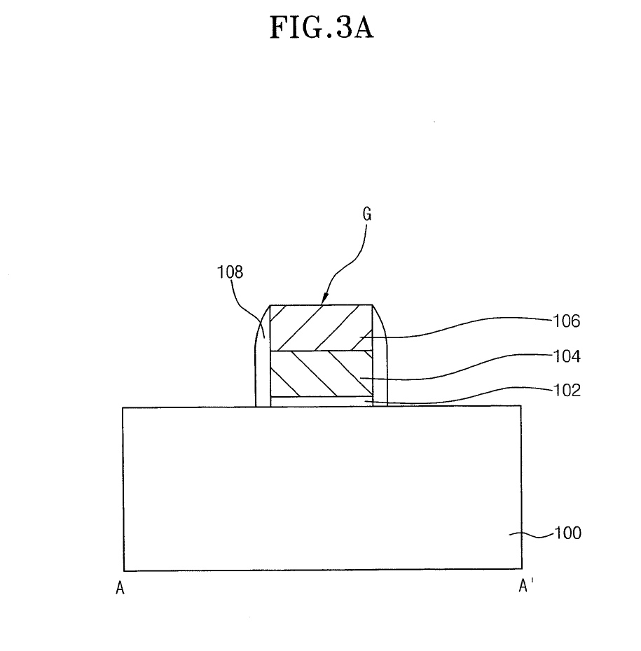

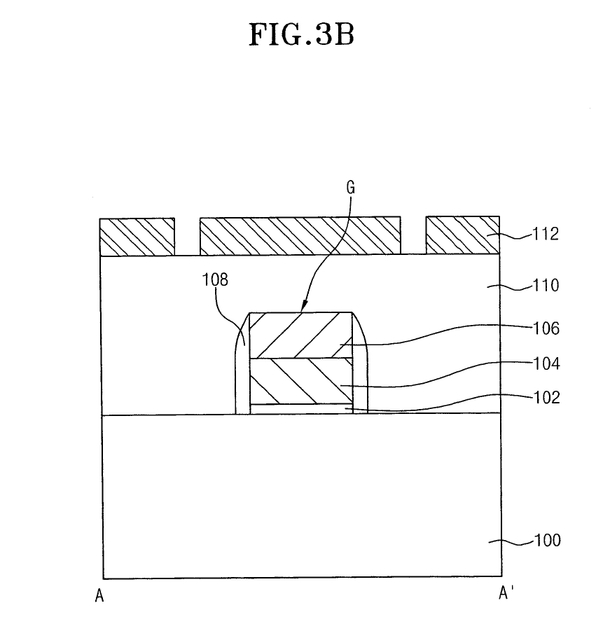

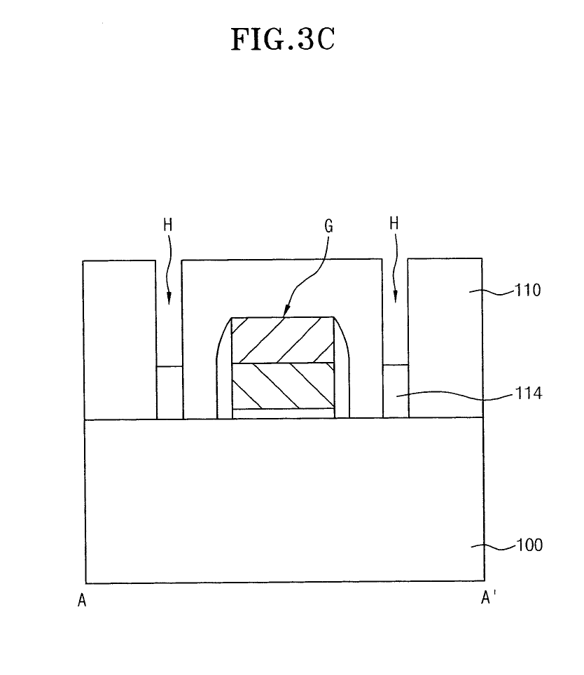

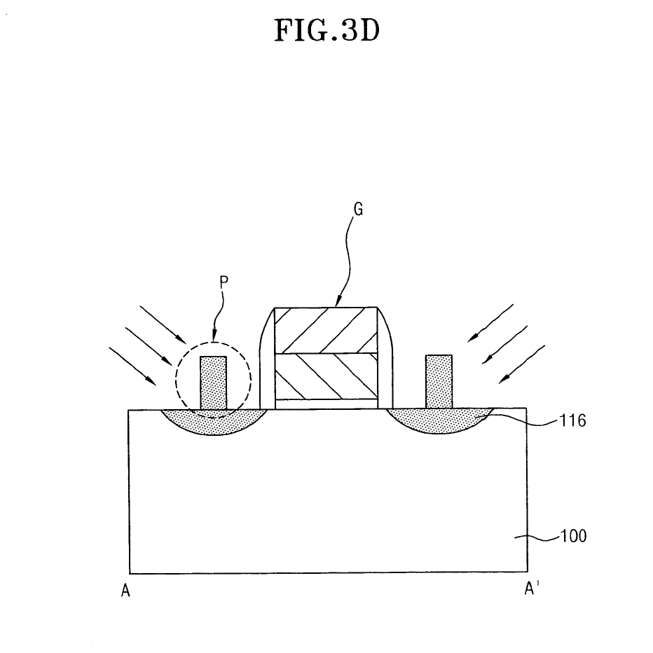

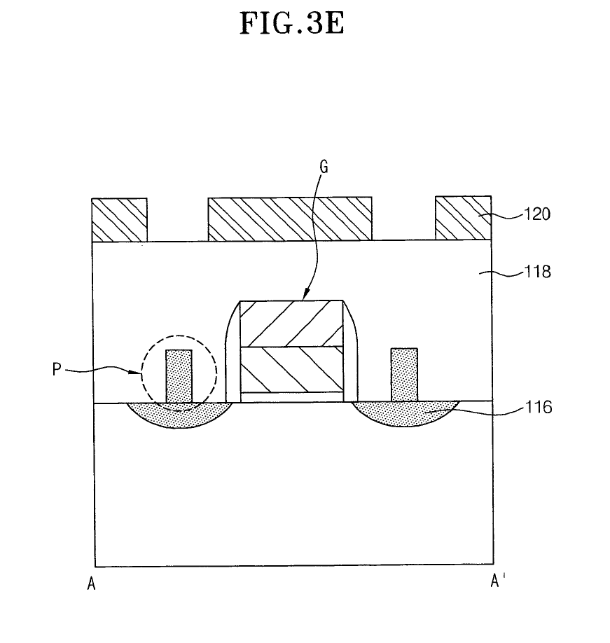

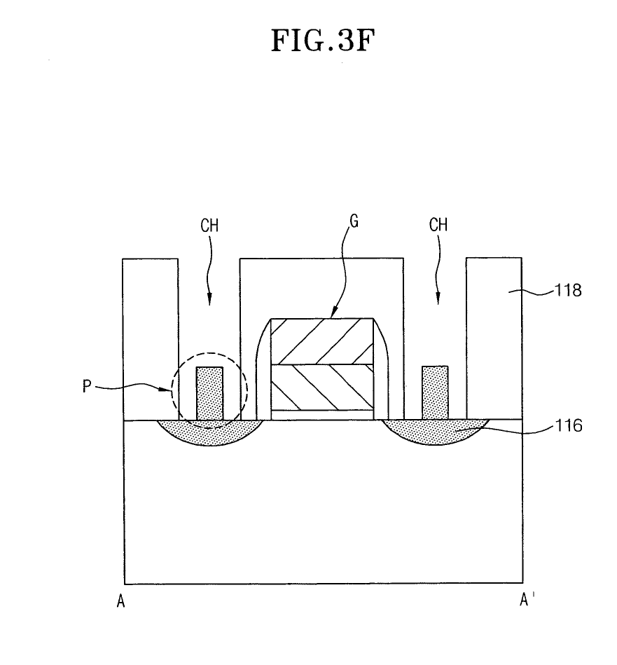

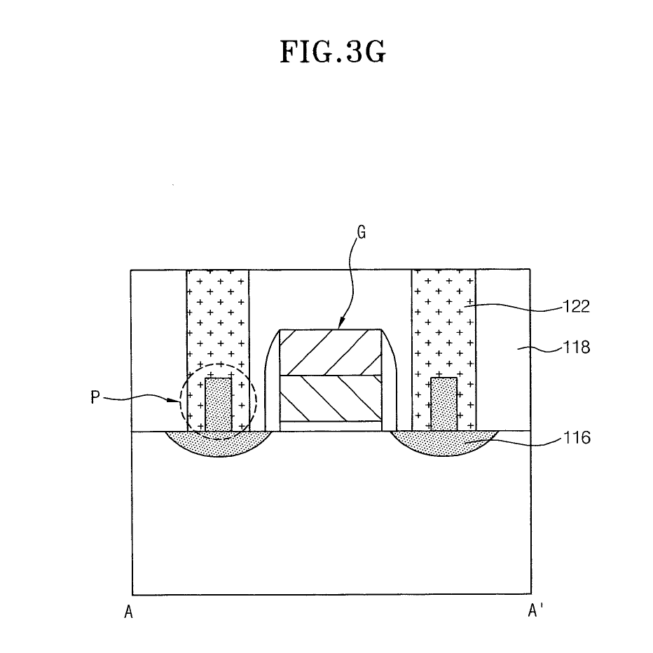

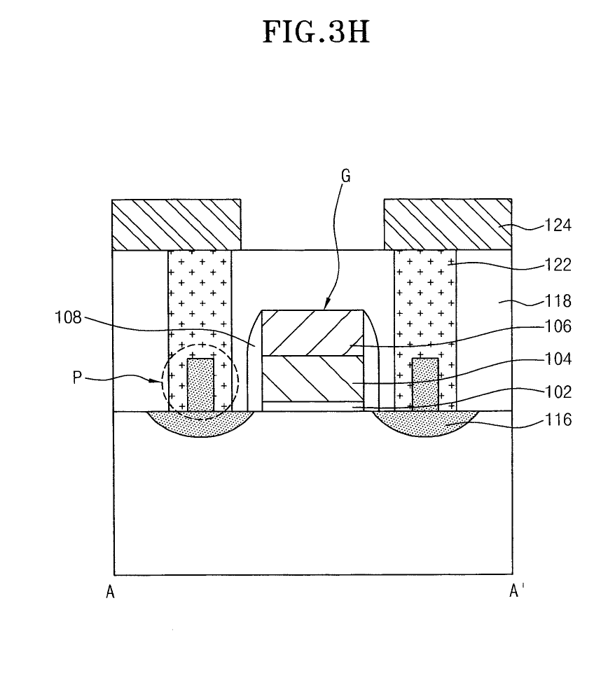

FIGS. 2A through 2H are plan views illustrating the process steps of a method for manufacturing a semiconductor device in accordance with an embodiment of the present invention and FIGS. 3A through 3H are cross-sectional views taken along the line A-A′ of FIGS. 2A through 2H respectively which illustrate the process steps of a method for manufacturing a semiconductor device in accordance with an embodiment of the present invention.

Referring to FIGS. 2A and 3A, the gate insulation layer 102, the gate conductive layer 104 and the gate hard mask layer 106 are sequentially formed over the semiconductor substrate 100. The gate hard mask layer 106, the gate conductive layer 104 and the gate insulation layer 102 are etched to form the gate G over the semiconductor substrate 100. The spacer 108 is formed on both side walls of the gate 108.

Referring to FIGS. 2B and 3B, a sacrifice layer 110 is formed over the semiconductor substrate 100 so as to cover the gate G including the spacer 108. It is preferable to use an insulating material to form the sacrifice layer 110. A first mask pattern 112 exposing at least some portion of the semiconductor substrate 100 corresponding to both sides of the gate G, preferably a portion of the sacrifice layer 110 at an upper central portion of a junction region forming portion is formed over the sacrifice layer 110.

Referring to FIGS. 2C and 3C, the exposed portion of the sacrifice layer 110 is etched using the first mask pattern as an etching barrier to form a hole H exposing a portion of the semiconductor substrate 100 corresponding to both sides of the gate G. The hole H is formed so as to have a narrower width than the width of the junction region forming portion corresponding to both sides of the gate G and thus only a portion of the junction region forming portion corresponding to both sides of the gate G is exposed. Then, the first mask pattern is removed. The epitaxial silicon layer 114 is grown over the portion of the semiconductor substrate 100 exposed by the hole H according to, for example, SEG (selective epitaxial growth) process to form the projection P.

Referring to FIGS. 2D and 3D, after the sacrifice layer 110 is removed, impurities are ion implanted into the projection P and the surface of the semiconductor substrate 100 corresponding to both sides of the gate G to form the junction region 116. The ion implantation of the impurities is preferably performed in a tilt ion implantation method at an implantation angle of 5 to 45° in four directions.

In the present invention, the impurities are ion implanted from the surface of the semiconductor substrate 100 corresponding to both sides of the gate G to the inside of the projection P through the ion implantation method, and therefore the junction region 116 including the projection P projecting from the surface of the semiconductor substrate 100 can be formed. Also, in the present invention, since the impurities are ion implanted into the inside of the projection P in concentrated areas, it is possible to form a shallower junction region in the surface of the semiconductor substrate 100 than that of the prior art.

Referring to FIGS. 2E and 3E, the insulation layer 118 is deposited so as to cover the gate G over the semiconductor substrate 100 formed with the junction region 116 including the projection P and then a surface of the insulation layer 118 is subsequently planarized. A second mask pattern 120 having an opening S for exposing a portion of the insulation layer 118 in the upper portion of the junction region 116 is formed over the planarized insulation layer 118. The opening portion S of the second mask pattern 120 is formed in a slit shape as shown in FIG. 2E.

Referring to FIGS. 2F and 3F, the exposed portion of the insulation layer 118 is etched using the second mask pattern as an etching barrier to form a slit type contact hole CH exposing the junction region 116 including the projection as a whole. Then, the second mask pattern is removed.

Referring to FIGS. 2G and 3G, a plug conductive layer is deposited over the insulation layer 118 to fill the contact hole CH. Before the plug conductive layer is deposited, further ion implantation into the junction region 116 including the projection may be performed in order to further improve the contact resistance. The plug conductive layer is removed so as to expose the insulation layer 118 to form the slit type contact plug 122 in contact with the junction region 116 in the inside of the contact hole CH. The contact plug 122 is formed so as to cover the projection P of the junction region 116.

Referring to FIGS. 2H and 3H, a conductive layer for the bit line is deposited over the insulation layer 118 including the contact plug 122. The conductive layer for the bit line is etched to form the bit line 124 in contact with the contact plug 122.

After that, though not shown, a series of known follow-up processes are sequentially performed to complete the manufacture of the semiconductor device in accordance with an embodiment of the present invention.

As is apparent from the above description, in the present invention, since the junction region including the projection projecting from the surface of the semiconductor substrate is formed and the contact plug is formed over the junction region so as to cover the projection, contact area between the junction region and the contact plug is increased.

Therefore, in the present invention, contact resistance between the junction region and the contact plug is increased through the increase in the contact area thereby enhancing the device characteristics and reliability. Also, in the present invention, since the impurities are ion implanted into the projection in concentrated areas when performing further ion implantation for improving the contact resistance of the contact plug, it is possible to prevent a reduction in threshold voltage caused by excessive ion implantation of the impurities into the surface of the semiconductor substrate.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor device, comprising:
a gate formed over a semiconductor substrate;
a junction region formed in a portion of the semiconductor substrate corresponding to both sides of the gate and including a projection, of which at least some portion thereof projects from the surface of the portion of the semiconductor substrate; and
a contact plug formed so as to cover the projection.

2. The semiconductor device according to claim 1, wherein the projection is formed of an ion implanted epitaxial silicon layer.

3. The semiconductor device according to claim 1, further comprising a bit line formed so as to be in contact with the contact plug.

4. A method for manufacturing a semiconductor device, comprising the steps of:
forming a gate over a semiconductor substrate;
forming a projection over at least some portion of the semiconductor substrate corresponding to both sides of the gate;
ion implanting impurities into the projection and a surface of the semiconductor substrate corresponding to both sides of the gate to form a junction region including the projection; and
forming a contact plug so as to cover the projection.

5. The method according to claim 4, wherein the projection is formed of an epitaxial silicon layer.

6. The method according to claim 5, wherein the epitaxial silicon layer is formed in a selective epitaxial growth process.

7. The method according to claim 4, wherein the step of forming the projection includes the steps of:
forming a sacrifice layer over the semiconductor substrate formed with the gate;
etching the sacrifice layer to form a hole exposing at least some portion of the semiconductor substrate corresponding to both sides of the gate;
forming the epitaxial silicon layer over the exposed portion of the semiconductor substrate; and
removing the sacrifice layer.

8. The method according to claim 6, wherein the hole is formed so as to have a smaller width than the width of the junction region.

9. The method according to claim 4, wherein the step of forming the junction region is performed in a tilt ion implantation method.

10. The method according to claim 9, wherein the tilt ion implantation method is performed at an implantation angle of 5 to 45°.

11. The method according to claim 9, wherein the tilt ion implantation method is performed in four directions.

12. The method according to claim 4, wherein the step of forming the contact plug includes the steps of:
forming an insulation layer so as to cover the junction region and the gate over the semiconductor substrate formed with the junction region;
etching the insulation layer to form a contact hole exposing the portion of the semiconductor substrate corresponding to both sides of the gate including the junction region;
depositing a conductive layer over the insulation layer so as to fill the contact hole; and
removing the conductive layer so as to expose the insulation layer.

13. The method according to claim 4, further comprising, after the step of forming the contact plug, the step of forming a bit line in contact with the contact plug.
